(19) United States
(12) Patent Application Publication
(10) Pub. No.: US 2004/0078104 A1
(43) Pub. Date: Apr. 22, 2004

(54) Method and apparatus for an in-vehicle audio system

(75) Inventors: Cong Nguyen, Cupertino, CA (US); Tatsuo Yamamoto, San Mateo, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: HITACHI, LTD., Tokyo (JP)

(21) Appl. No.: 10/278,586

(22) Filed: Oct. 22, 2002

(51) Int. Cl. H04B 1/00; G06F 17/00; H03G 3/00

(52) U.S. Cl. 700/94; 381/104; 381/86

(57) ABSTRACT

An in-vehicle audio system provides audio paths for a variety of audio sources. Volume control is provided to vary the volume level of audible sound of one or more audio sources when produced by a plurality of speakers. Audio path control is provided to enable communication with a communication device to occur at the same time the audio is delivered to the speakers.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

The present invention is related generally to audio systems and more particularly to methods and apparatus for an in-vehicle audio system for providing audio to occupants in a vehicle.

“A journey of 1,000 miles begins with the first step.” When Confucius penned these words, the ancient philosopher probably never imagined that the modern traveler would have at her disposal a myriad of distractions to while away the tedium of a long journey, or just a quick stop to the corner store.

Automobile travel is one of the most recognizable modes of transportation, and the car radio is one of the earliest gadgets to become a common sight in any car. With continuing advances in electronic miniaturization and functional integration, the radio has been upgraded/supplanted by a variety of forms of in-vehicle entertainment and utility devices.

Forms of audio entertainment include radio, audio tape players such as eight-track tape, audio cassette tapes, and various formats of digital audio tape devices. Other digital media include compact disc players, various formats of sub-compact disc devices, and so on. MP3 player devices are becoming common, providing hundreds of hours of music in a very small form factor. These devices can be interfaced with existing audio systems and offer yet another alternative source for audio content, such as music, or audio books, and so on.

The development of cellular telephone technology has resulted in the proliferation of “cell” phones. More often than not, automobile occupants, drivers and passengers alike, can be seen using a cell phone. “Hands-free” operation is a convenient feature, especially for the driver, allowing the driver to converse and control telephone functions by voice activation. Developments in wireless technology have resulted in short range wireless communications standards such as IEEE 811 and Bluetooth. These wireless techniques can facilitate the use of hands-free cell phone usage.

In-vehicle navigation systems are a feature found in some automobiles. Voice synthesis technology allows for these systems to “talk” to the driver to direct the driver to her destination. Voice recognition systems provide the user with vocal input, allowing for a more interactive interface with the navigation system.

As cell phone technology continues to improve, access to the Internet can become a common occurrence in an automobile environment. The Internet can be an alternative source of music, it can provide telephony services, and it can provide navigation services. Presently, telephonic devices provisioned with in-band signaling (IBS) modems can be used to access services provided over the cell phone network, not unlike accessing the Internet. IBS is a communication protocol that uses the voice channel in areas where digital service is not available, occupying the audio frequency bands to transmit data. [please review this description of IBS and correct as needed]

With all of this audio activity potentially happening in the automobile, it could become inconvenient to use a particular function. For example, if the children are listening to their music, the parents may not be able to hear the navigation system giving them directions to the amusement park. As another example, it can be difficult to carry on a conversation on the phone if the MP3 player is being played at a high volume. Typically, someone has to be asked to turn down the music; sometimes, more than once in the case of an annoyed parent and a non-responsive child. Sometimes, the distraction is simply the action of muting where, for example, the cell phone user may have to negotiate driving, holding the cell phone while talking, and reaching to turn off the radio.

A need exists therefore to handle a changing audio environment in an automobile where different audio sources may contend for the same audience. Generally, in any apparatus for transporting people having an in-vehicle audio system, there is a need to manage multiple sources of audio information more effectively than is presently available. The audio information can be music or informational in nature.

### SUMMARY OF THE INVENTION

In an embodiment of the invention, an in-vehicle audio system delivers first audio information to a plurality of speakers. When second audio information is detected, at least some of the speakers receive an audio signal representative of the first audio and the second audio information. Sound produced at those speakers comprise a first sound component representative of the first audio information and a second sound component representative of the second audio information. The volume level of the first sound component is lower than the sound produced at the speakers that play back only the first audio component.

In another embodiment of the invention, an in-vehicle audio system delivers first audio information to a plurality of speakers over a first coder/decoder (codec) device. Communication can be established between a communication device and a controller of the in-vehicle audio system while the controller continues to deliver the first audio information to the speakers.

### BRIEF DESCRIPTION OF THE DRAWINGS

The present invention can be appreciated by the description which follows in conjunction with the following figures, wherein:

FIG. 1 shows a generalized high level system block diagram of an in-vehicle audio system in accordance with a example embodiment of the present invention;

FIG. 2 is a generalized block diagram, illustrating a configuration of codecs in accordance with an embodiment of the present invention;

FIG. 3 is a generalized block diagram, illustrating another configuration of codecs in accordance with another embodiment of the present invention;

FIG. 4 shows the audio path when a single audio source is presented;

FIG. 5 is a high-level generalized flow chart for processing audio streams in accordance with the present invention;

FIG. 6 shows the audio paths in a configuration when two audio streams are presented to the audio system;

FIG. 7 shows the audio paths in another configuration when two audio streams are presented to the audio system;

FIG. 8 illustrates a hands-free operation for cell phone usage according an example embodiment of the present invention;

FIG. 9 illustrates an alternate hands-free operation for cell phone usage according to another example embodiment of the present invention;

FIG. 10 is a high level generalized flow chart for performing noise cancellation;

FIG. 11 shows the audio paths for noise cancellation;

FIG. 12 shows an alternate audio path for noise cancellation;

FIG. 13 is a high level generalized flow chart for processing using an in-band signaling modem;

FIG. 14 illustrates the audio paths for an in-band signaling modem configuration; and

FIG. 15 illustrates an alternate audio path configuration of FIG. 14.

### DESCRIPTION OF THE SPECIFIC EMBODIMENTS

It will be appreciated that the present invention described below is applicable not only to automobiles, but more broadly to any vehicle. Random House's 1995 publication of its Webster's College Dictionary defines a “vehicle” as “any means in or by which someone or something is carried or conveyed; means of conveyance or transport.” For the purposes of the present invention, it is understood that the term “vehicle” will refer all to manner of transporting people, including land vehicles, water vessels, and air vessels.

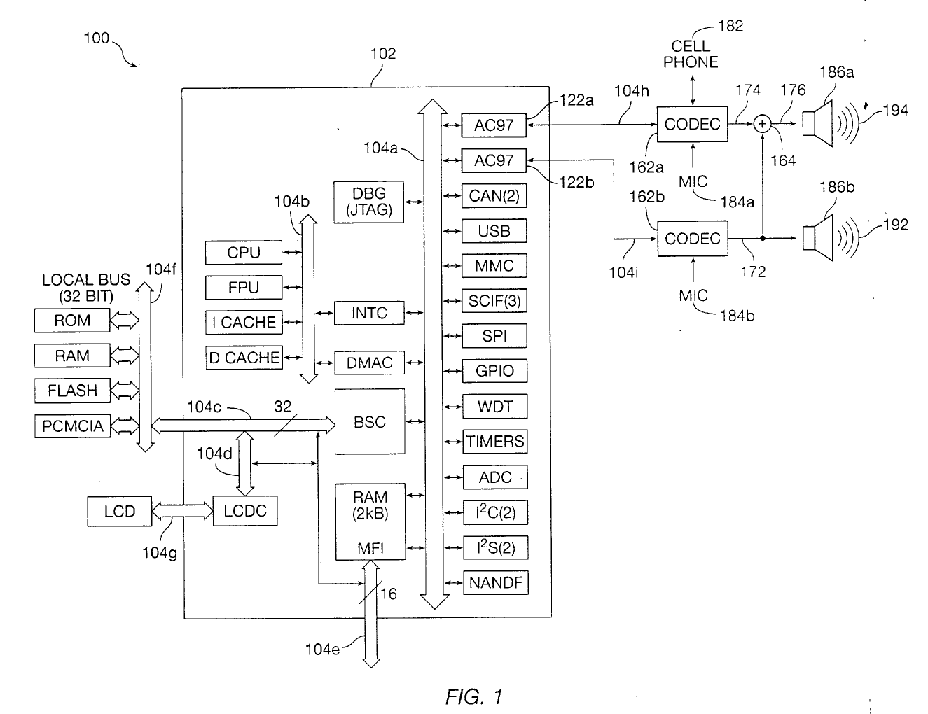

Referring to FIG. 1, a high level generalized system block diagram depicts an example embodiment of an in-vehicle audio system 100 in accordance with the present invention. The system includes a microcontroller 102 coupled via an external buses 104e to 104i to various external components. In the example embodiment shown in the figure, the microcontroller is from the SuperH family of microcontrollers produced and sold by Hitachi, Ltd. and Hitachi Semiconductor (America) Inc. Although not germane to the description of the invention the particular device used can be identified by the Hitachi part number HD6417760BP200D. It can be appreciated, that any commercially available microcontroller device, and more generally, any appropriate computer processing device.

An external bus 104f provides an audio path for the exchange of control signals and digital data between the microcontroller 102 and various external components. For example, many typical designs are likely to include a ROM (read-only memory), containing all or portions of an operating or control program for the microcontroller. A RAM (random access memory) is another common element. A Flash RAM can be provided to store a variety of information such as user configurations and settings, and so on which require somewhat more permanent but otherwise re-writable storage. A data connection port can be provided for attachment of additional devices. In the example embodiment shown in FIG. 1, the data connection port is based on the PCMCIA (Personal Computer Memory Card International Association) standard. An LCD (liquid crystal display) monitor can be provided to facilitate user interactions with the audio system, and to provide other display functions. For example, in a particular embodiment of the audio system, a navigation control system can be provided. In such a case, the LCD could double as the display device for the navigation system.

Other external components include coder/decoder (codec) devices 162a and 162b, and a speaker system component. In the particular embodiment shown, the speaker system component comprises a first speaker system 182a and a second speaker system 182b. Additional details of these components will be presented below.

A brief description of various internal components of the microcontroller 102 shown in FIG. 1 will now be presented. As indicated above, the particular microcontroller shown is for a particular implementation of an example embodiment of an in-vehicle audio system according to the present invention. The microcontroller shown is a conventional device comprising components typically present in such devices. The internal components to be discussed shortly, however, are specific to the particular microcontroller used. It can be appreciated that those of ordinary skill in the relevant arts will understand that similar functionality can be realized in other microcontroller architectures, and in fact, that such functionality can be readily obtained with most digital computing devices in conjunction with appropriate supporting logic and/or software.

The microcontroller 102 comprises standard processing logic such as a central processing unit (CPU) which can include an instruction decoder, an arithmetic logic unit, and so on. A floating-point processing unit is typically included to provide numeric computation capability. Registers (not shown) are also provided to support the data manipulations performed by the CPU and FPU. In this particular implementation, the microcontroller is a RISC-based machine and so the registers are organized as a bank of “register files.” It can be appreciated that in other processor architectures (e.g., CISC, Harvard), the registers may be organized and identified by function, e.g., accumulator, index register, general purpose registers, and so on. Additional support logic typically can include an instruction cache (I CACHE) and a data cache (D CACHE). Various internal buses 104a-104d are provided for moving data and transferring control signals among the constituent components of the microcontroller 102.

Two AC97 controllers 122a and 122b are provided. These controllers generate signals for controlling the codecs which implement the audio processing functions of the AC97 architecture. In the particular microcontroller 102 shown in FIG. 1, the controllers are integrated in the microcontroller logic. While this configuration is available in some microcontroller devices, it can be appreciated that in other architectures the AC97 controllers can be provided off-chip as external logic.

The microcontroller 102 shown in FIG. 1 includes additional conventional components such as an interrupt controller (INTC) and a direct memory access controller (DMAC). Still other components include: two control area network (CAN) modules; a universal serial bus (USB) controller for interfacing to USB devices; a multi-media card (MMC) interface; three serial communication interfaces, each with a FIFO (first in-first out) buffer (SCIF); a serial protocol interface (SPI); general purpose input/output pins (GPIO); a watchdog timer (WDT); timer modules (TIMERS); and an analog-to-digital converter module (ADC). The microcontroller design includes two inter-IC bus modules (I²C) for coordinating operation among the external logic, and a NAND gate flash memory (NANDF). The microcontroller further comprises a JTAG-compliant (Joint Test Action Group) debugging module (DBG JTAG); a bus state controller (BSC) for coordinating access among different memory types; and a multi-function interface (MFI) for providing high-speed data transfer between external devices (e.g., baseband processors, etc.) which cannot share an external bus.

An LCD controller (LCDC) is provided to display various user-relevant data to the LCD. Data buses 104d and 104g are provided for the data and control signals to facilitate the data display function. In addition, the multi-function interface (MFI) can be multiplexed with the LCD over a data bus 104e to allow a data connection to an external device such as a baseband processor, for example.

As shown in the exemplar of FIG. 1, audio processing for the in-vehicle audio system is provided by two codec devices 162a and 162b. Each codec is controlled by and exchanges data with its corresponding AC97 controller over it associated bus. Thus, for example, the AC97 controller 122a is coupled via a bus 104h to the codec 162a, and similarly the AC97 controller 122b is coupled via a bus 104i to the codec 162b. In this particular implementation shown, the codecs are LM4549 audio codecs manufactured and sold by National Semiconductor Corp.

In this particular embodiment, the output of each codec is an analog audio signal suitable for driving a speaker subsystem. It can be appreciated that other codec designs may produce an audio signal that is a digital signal which can serve as an audio source to a speaker subsystem having input circuitry suited for receiving digital input and producing audible sound.

The codec 162a produces an audio signal 174 which feeds into an input of an audio mixing circuit (mixer) 164. Similarly, the codec 162b produces an audio signal 172 which feeds into another input of the mixer. The mixer produces an audio signal 176 which is a composed of the audio signals 174 and 172. The audio signal 176 can serve as an audio source to a first speaker system 186a. The resulting audible sound 194 produced by the first speaker system comprises a sound component representative of the audio signal 172 and another sound component representative of the audio signal 174. As can be seen in FIG. 1, the audio signal 172 is also provided to a second speaker system 186b. The resulting audible sound 192 produced by the second speaker system comprises a sound component representative of the audio signal 172.

In the case of an in-vehicle audio system for an automobile, the first speaker system 186a can be a set of speakers positioned toward the forward part of the automobile, while the second speaker system 186b can be a set of speakers positioned toward the rear of the automobile. It will be appreciated from the foregoing and the following descriptions that other speaker configurations may be more appropriate for a given in-vehicle listening environment. Generally, the first speaker system is disposed in a first listening area in the vehicle and the second speaker system is disposed in a second listening area where it may be desirable to vary the volume of audio content being presented in one listening area independent of the other listening area.

FIG. 1 shows further that a communication device 182 such as the familiar cell phone can be accessed by the in-vehicle audio system using techniques according to the invention. The communication device could be a modem in a portable personal computer. In general, the communication device can be any suitable device for providing two way communication. Microphone devices 184a and 184b are also provided. Like the communication device, the microphones can also be used with the in-vehicle audio using techniques according to the invention. These operations will be discussed in further detail below.

Operation of the microcontroller 102 can be provided by computer program code (control program, executable code, etc.). The program code can provide the control and processing functions appropriate for operation of the audio system according to the present invention. Typically, in a microcontroller-based architecture, the executable program code is “burned” into a non-volatile memory, such as read-only memory (ROM). Thus, in an example embodiment of the present invention, the control program can be provided in the ROM shown in FIG. 1. In a different architecture, it may be more appropriate that the program code is stored on a disk storage system and loaded into the microcontroller 102 at run time. It might be appropriate to implement some of the control and/or processing functions in hardware for performance reasons, reliability, and so on. It can be appreciated that the control and processing functions can be implemented in software, or hardware, or combinations of software and hardware.

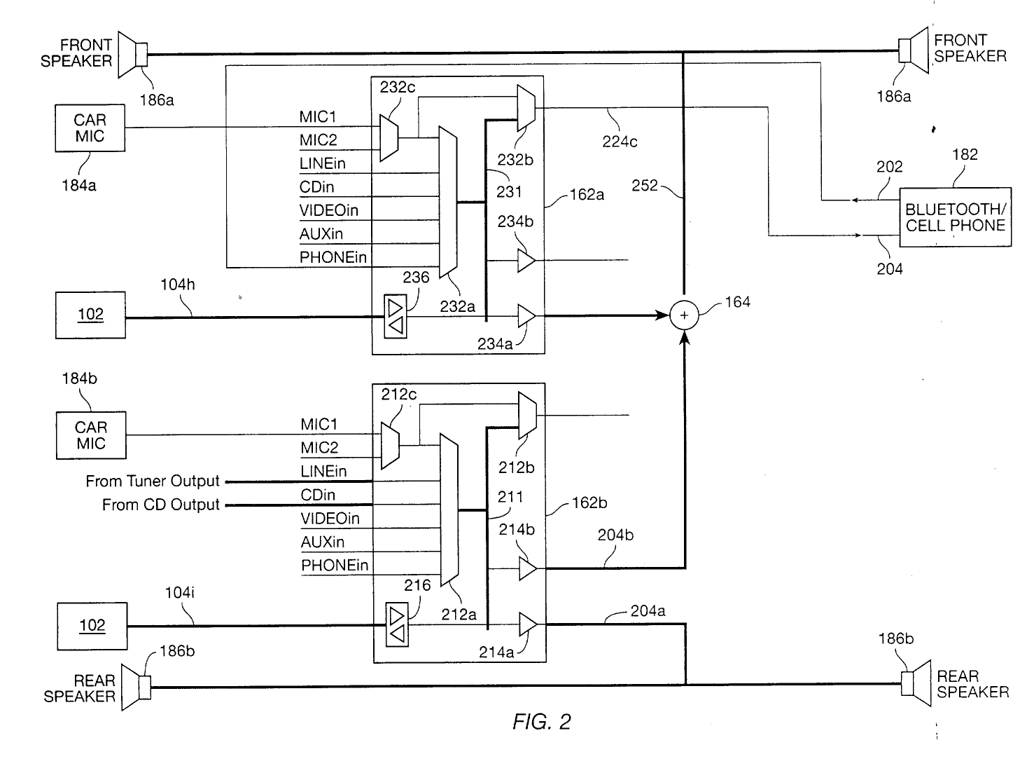

FIG. 2 is a generalized block diagram showing additional detail of the configuration of the codecs 162a and 162b according to an example embodiment of the present invention. The block diagram for each of the codecs highlights functions of the codec that are relevant to the invention. The following functionality is represented in the figure by specific elements. One of ordinary skill in the relevant arts will appreciate that the functionality described is present in most if not all codec designs, and can be implemented as a single integrated circuit device, by discrete components, or by some combination of discrete components and IC devices.

Thus, with respect to the codec 162a, the codec can be provided with plural inputs for receiving a variety of audio sources, including: two microphone inputs (MIC1, MIC2), a LINEin input, a CDin input, an AUXin input, and a PHONEin input. The bus 104h from the AC97 controller 122a is coupled to a serial data out (SDOUT) input pin of the codec.

The relevant logic of the codec 162a includes selection functionality as represented by a multiplexer (mux) 232c for selecting between the two microphone inputs (MIC1, MIC2), and a multiplexer 232a for selecting from among the LINEin input, the CDin input, the AUXin input, the PHONEin input, an output of the mux 232c, and the output of a transceiver 236. Another multiplexer 232b selects between the output of mux 232c and an output of mux 232a and provides the selection to an output 224c.

The serial data out (SDOUT) input feeds into the transceiver 236 to allow bi-directional flow of digital signals along the bus 104h. It can be appreciated that appropriate circuitry is provided to support analog-to-digital conversion and digital-to-analog conversion as needed, but is not otherwise shown to avoid cluttering the diagram.

Signal gain control functionality is represented in FIG. 2 as amplification circuits 234a and 234b, each being configured to receive, as an input signal, either the output of the mux 232a or the SDOUT line. The amplifiers perform a gain/attenuation/mute (GAM) operation on the input signal. The amplifier 234a provides an “amplified” signal to an output 224a; the amplified signal being an amplification, attenuation, or muting of its input signal. Similarly, the amplifier 234b provides its input signal, as an amplified signal, to an output 224b.

The codec 162b is similarly configured with similar functionality. Thus, the codec is provided with plural inputs for a variety of audio sources, including: two microphone inputs (MIC1, MIC2), a LINEin input, a CDin input, an AUXin input, and a PHONEin input. The bus 104i from the AC97 controller 122b is coupled to a serial data out (SDOUT) input pin of the codec.

As with the codec 162a, the relevant logic of the codec 162b includes a multiplexer (mux) 212c for selecting between the two microphone inputs (MIC1, MIC2), and a multiplexer 212a for selecting from among the LINEin input, the CDin input, the AUXin input, the PHONEin input, an output of the mux 212c, and an output of a transceiver 216. Another multiplexer 212b selects between the output of mux 212c and an output of mux 212a, and couples the selection to an output 204c.

The serial data out (SDOUT) input feeds into the transceiver 216 to allow bi-directional flow of digital signals along the bus 104i. It can be appreciated that appropriate analog-to-digital conversion and vice-versa can be performed as needed, as mentioned above.

Each of the two amplification functional units 214a and 214b is configured to receive as an input signal either the output of the mux 212a or SDOUT. The amplifiers perform a gain/attenuation/mute (GAM) operation on the input signal to produce an amplified signal. The amplifier 214a provides an amplified signal at its output 204a. The amplifier 214b, likewise, provides an amplified signal at its output 204b. The output 204b is coupled to provide the amplified signal to the speaker system 186b.

The audio mixing circuit 164 includes a first input coupled to the output 224a of the codec 162a and a second input coupled to the output 204b from the codec 162b. The mixing circuit further includes an output 252 which is coupled to the speaker system 186a. The output of the mixing circuit provides an audio signal which represents a combination of the audio provided at the output 204b from the codec 162b and the output 224a from the codec 162a.

FIG. 2 also shows a communication device 182, such as a cell phone, a modem, etc., and can be a wired or wireless device (e.g., Bluetooth-based). Communication from the device to the audio system occurs over an incoming channel 202, while outgoing communication (from the audio system to the device) occurs over an outgoing channel 204. Note that the incoming channel can be a wireless connection, as can the outgoing channel.

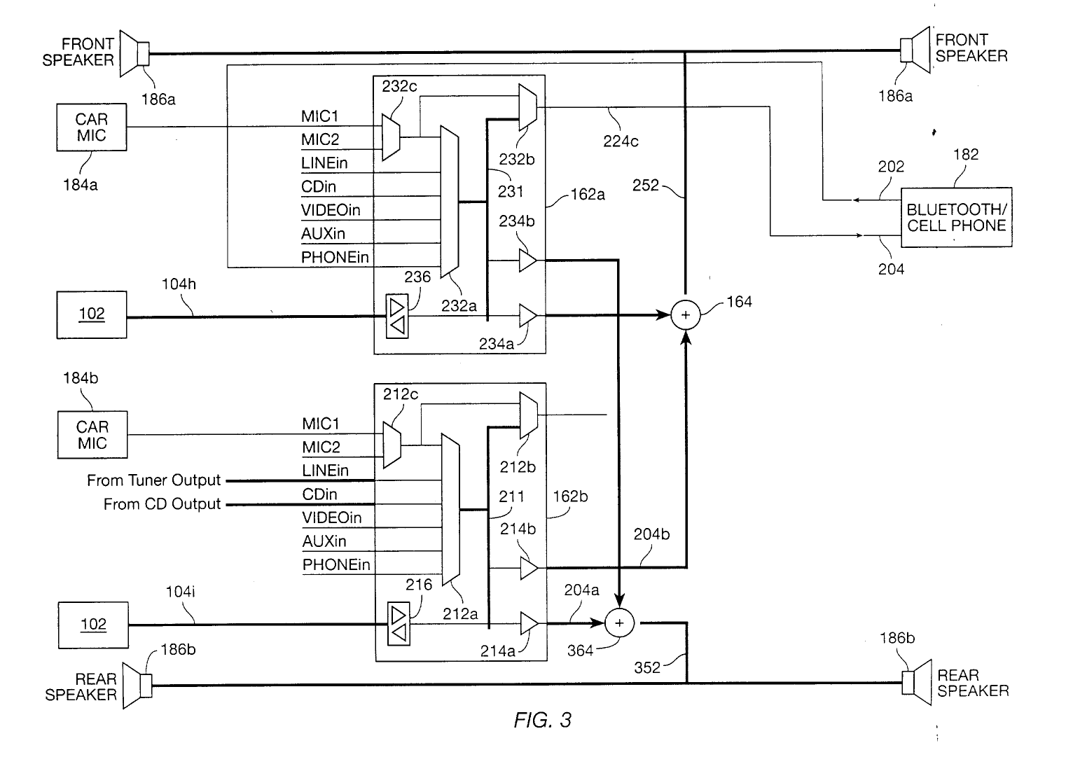

FIG. 3 is a generalized block diagram showing detail of a configuration of the codecs 162a and 162b according to another example embodiment of the present invention. The block diagram for each the codecs highlights functional aspects of the codec logic that is relevant to the invention. The specific implementation details can be easily understood by those of ordinary skill in the relevant arts.

The codec 162a can be provided with plural inputs for receiving a variety of audio sources, including: two microphone inputs (MIC1, MIC2), a LINEin input, a CDin input, an AUXin input, and a PHONEin input. The bus 104h from the AC97 controller 122a is coupled to a serial data out (SDOUT) input pin of the codec.

The relevant logic of the codec 162a includes a multiplexer 332c for selecting between the two microphone inputs (MIC1, MIC2), and a multiplexer 332a for selecting from among the LINEin input, the CDin input, the AUXin input, the PHONEin input, an output of the mux 332c, and the output of a transceiver 336. Another multiplexer 332b selects between the output of mux 332c and an output of mux 332a and provides the selection to an output 324c.

The serial data out (SDOUT) input feeds into the transceiver 336 to allow bi-directional flow of digital signals along the bus 104h. It can be appreciated that appropriate circuitry is provided to support analog-to-digital conversion and vice-versa as needed, but is not otherwise shown to avoid cluttering the diagram.

As can be seen in FIG. 3, the output of the mux 332a feeds into amplifiers 334a and 334b, as does SDOUT. The amplifiers perform a gain/attenuation/mute (GAM) operation on the input signal. The amplifier 334a provides an amplified signal to an output 324a. Similarly, the amplifier 334b provides its input signal to an output 324b.

The codec 162b shown in FIG. 3 is similarly configured. The codec is provided with plural inputs for a variety of audio sources, including: two microphone inputs (MIC1, MIC2), a LINEin input, a CDin input, an AUXin input, and a PHONEin input. The bus 104i from the AC97 controller 122b is coupled to a serial data out (SDOUT) input pin of the codec.

The relevant logic of the codec 162b includes a multiplexer (mux) 312c for selecting between the two microphone inputs (MIC1, MIC2), and a multiplexer 312a for selecting from among the LINEin input, the CDin input, the AUXin input, the PHONEin input, an output of the mux 312c, and the output of a transceiver 316. Another multiplexer 312b selects between the output of mux 312c and an output of mux 312a and provides the selection to an output 304c.

The serial data out (SDOUT) input feeds into the transceiver 316 to allow bi-directional flow of digital signals along the bus 104i. Appropriate analog-to-digital conversion and vice-versa are operations can be performed as needed.

The output of the mux 312a feeds into amplifiers 314a and 314b. Likewise, the SDOUT input line feeds into the amplifiers. The amplifiers perform a gain/attenuation/mute (GAM) function on the input signal to produce an amplified signal. The amplifier 314a provides the amplified signal to its output 304a. The amplifier 314b amplifies its incoming signal in a similar way to produce an amplified signal at its output 304b. The output 304b is coupled to provide the amplified signal to the speaker system 186b.

The audio mixing circuit 164 includes a first input coupled to the output 324a of the codec 162a, and a second input coupled to the output 304b from the codec 162b. The mixing circuit further includes an output 352 which is coupled to the speaker system 186a. The output of the mixing circuit provides an audio signal which represents a combination of the audio signals provided at both the output 304b from the codec 162b and the output 324a from the codec 162a.

A second audio mixing circuit 364 includes a first input coupled to the output 324b from the codec 162a and a second input coupled to the output 304a from the codec 162b. The second mixing circuit further includes an output 352 which is coupled to the speaker system 186b. The output of the second mixing circuit provides an audio signal which represents a combination of the audio signal provided both at the output 324b of codec 162a and output 304a of codec 162b.

FIG. 3 also shows a communication device 182, such as a cell phone, a modem, etc., and can be a wired or wireless device (e.g., Bluetooth-based). Communication from the device to the audio system occurs over an incoming channel 202, while outgoing communication (from the audio system to the device) occurs over outgoing channel 204.

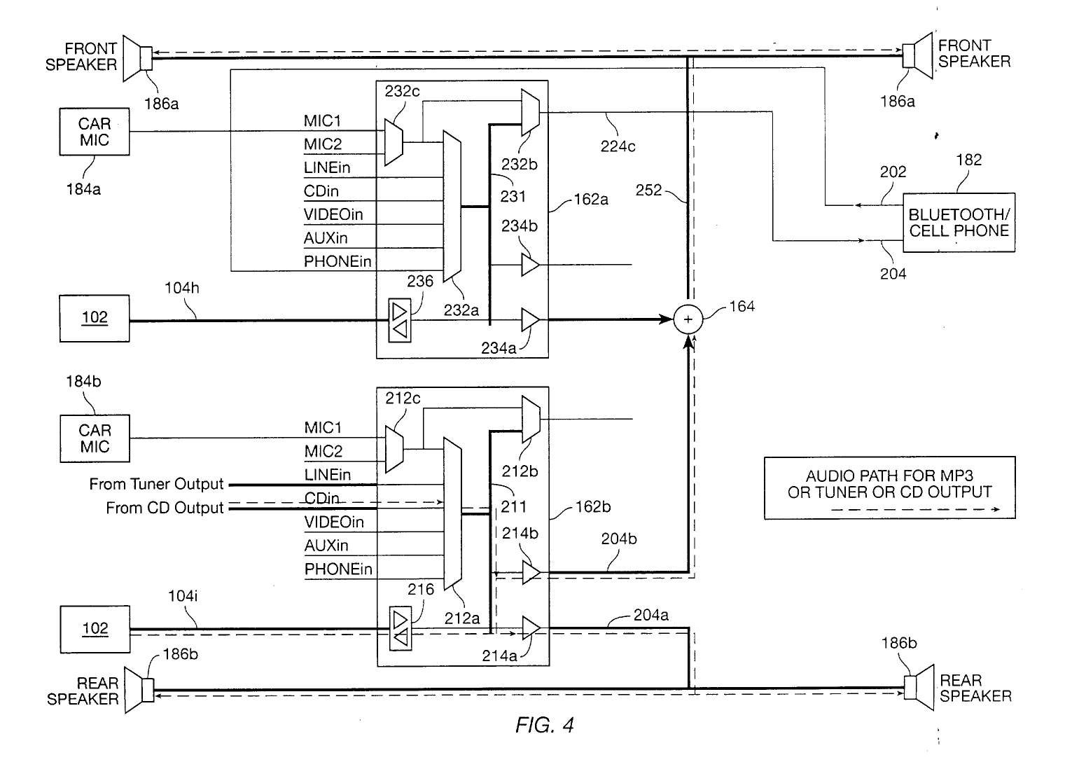

FIG. 4 illustrates the audio path in a simple operating scenario wherein audio information is provided by a single audio source. The figure shows, merely as an exemplar, processing of an MP3 audio stream. The audio source for the MP3 audio might be provided by an MP3 player interfaced with the audio system (FIG. 1) via the multi-function interface (MFI). It can be understood that the microcontroller 102 can be suitably controlled by software and/or hardware to access the MP3 stream from a device such as the MP3 player (or even the Internet) and deliver that stream via the AC97 controller 122a to the codec 162b as shown in the figure.

The codec 162b receives audio information (in the case a digital MP3 audio stream) from the AC97 controller 122a. The digital audio stream is then converted to an analog signal by appropriate D/A conversion circuitry (not shown). The analog signal is then provided to the speaker system 186b along an audio path comprising the output 204a of the codec. The analog signal is also provided to the speaker system 186a along an audio path comprising the output 204b and the output 252 of the audio mixing circuit 164. In this operating scenario, there is no signal on the output 224a of the codec 162a, and so the mixer simply outputs the signal it receives from the codec 162b.

It can be appreciated that various user-adjustable audio parameters can be implemented. For example, bass and treble adjustment functions can be provided. A volume control function can be provided, as well as fading and left/right balance controls. One of ordinary skill can easily realize any additional circuitry that might be required to provide these and other functions.

FIG. 4 shows an alternate audio path for a different audio source. For example, instead of an MP3 audio stream, the audio can be provided from a compact disc (CD) player (not shown). A CD player can provide the audio stream directly to the codec 162b via the CDin input of the codec. An appropriate codec control message can be sent from the microcontroller to the codec via the CPU link. Upon receiving the control message, the codec will select the Cdin input to provide the audio stream from that input to the outputs 204a and 204b of the codec, as shown by the dotted line. Although not shown, one can readily appreciate that another audio source such as a tuner can be provided to the speaker(s) 186a and 186b along a similar audio path via the codec 162b.

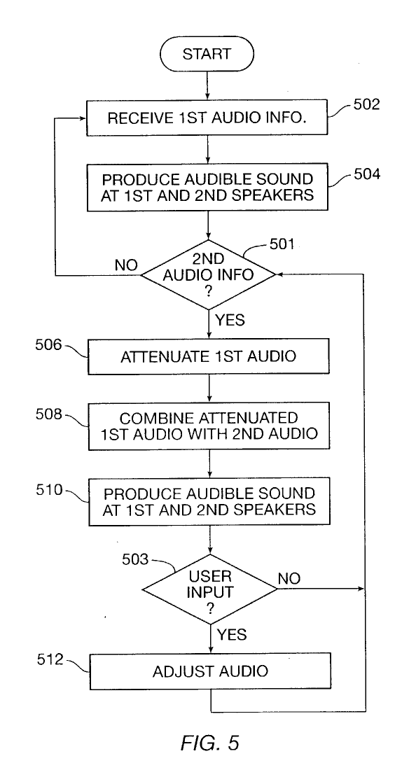

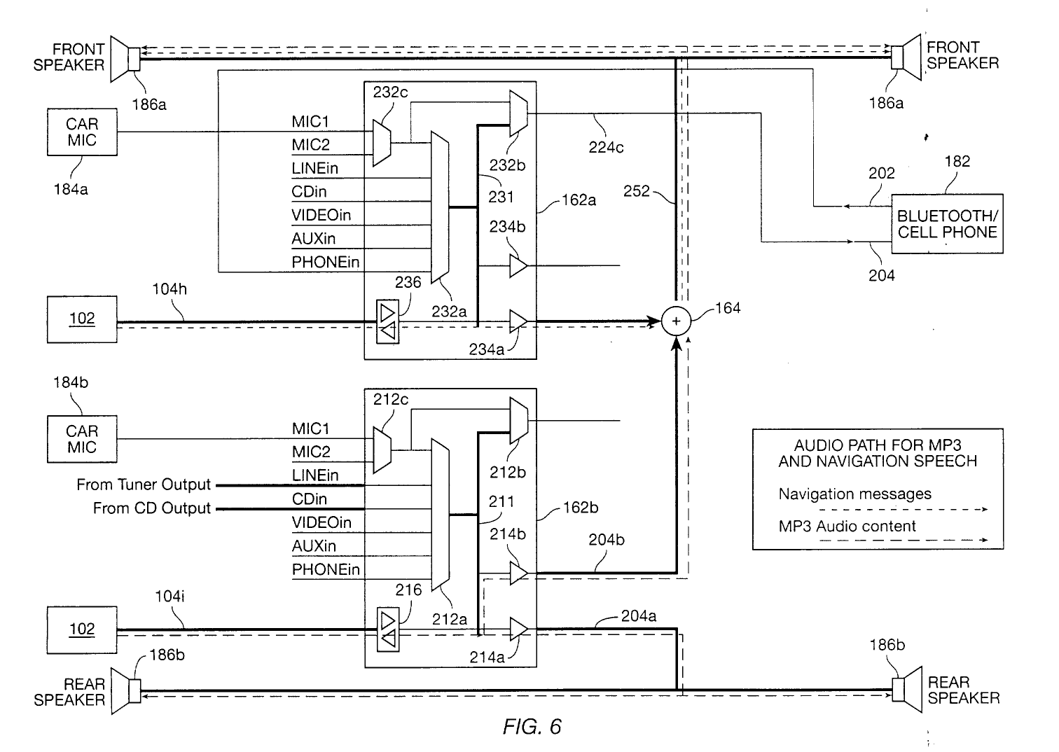

Referring now to FIGS. 5 and 6, the generalized flowchart of FIG. 5 illustrates the highlights of processing of audio streams according to the invention, as explained in conjunction with the operating scenario shown in FIG. 6. As noted above, the processing discussed in the flow charts that follow can be provided by any appropriate combination of control program and/or logic functions to detect various conditions and to generate control signals accordingly.

Thus, in a step 502, first audio information is received. FIG. 6, for example, shows an MP3 audio stream provided to the codec 162b. Audible sound representative of the first audio information is produced, in a step 504, at the speaker(s) 186a via an audio path comprising the output 204b of the codec 162b and the output 252 of the mixer 164. Similarly, audible sound is produced at the speaker(s) 186b via an audio path comprising the output 204a of the codec 162b.

Suppose that a second audio stream from another audio source is provided to the codec 162a. For example, FIG. 6 can represent a scenario where a navigation system is the source of a second audio stream (e.g., synthesized voice). The microcontroller 102 can interface with the navigation system, for example, via the multi-function interface (MFI) and deliver the navigation audio stream to the codec 162a via the AC97 controller 122a.

Thus, in a step 501, when a second audio source is detected, appropriate control signals are issued to the functional unit represented by the amplifier 214b to adjust the audio signal of the MP3 stream (step 506) such that the volume level of the sound produced by a speaker will be lower than the volume level of the sound produced from the signal provided by the amplifier 214a. The signal produced by the amplifier 214b is thus referred to generally as an altered-volume signal because the signal has been altered in some respect. More specifically, the signal can be referred to as a reduced-volume signal because the volume level has been reduced.

The navigation audio stream provided to the codec 162a is converted to an analog signal and provided via the amplifier 234a to the output 224a. The mixer 164 performs an audio mixing operation to combine, in a step 508, the navigation audio and the reduced-volume signal from the codec 162b to produce a combined signal. This signal is delivered, in a step 510, to the speaker(s) 186a which produce an audible sound comprising a sound component representative of the MP3 audio stream and a sound component representative of the navigation audio stream. The MP3 audio stream that is delivered to the speaker(s) 186b remains unchanged.

Consider the case where the speaker(s) 186a are front speakers and the speaker(s) 186b are rear speakers. The reduced-volume MP3 audio component of the sound produced by the front speakers allows the front passengers to hear the navigation audio component contained in the sound. However, sound produced by the rear speakers remains unchanged and thus allows passengers in the rear of the vehicle to continue enjoying the MP3 audio. When the navigation audio is terminated, step 501, appropriate control signals can be generated to restore the audio signal produced by the amplifier 214b in the codec 162b, thus restoring the volume level of the sound produced by the front speakers.

It can be appreciated that the terms “front” and “rear” speakers are merely relative terms. In a different vehicle, the speaker(s) 186a and 186b might be left-side and right-side speakers, where it may be desirous to output the second audio source at the left-side speakers.

To complete the flowchart of FIG. 5, audio adjustments can be provided to the user. When a user adjustment is made, in a step 503, the appropriate adjustment can be executed by appropriate hardware and/or software (step 512).

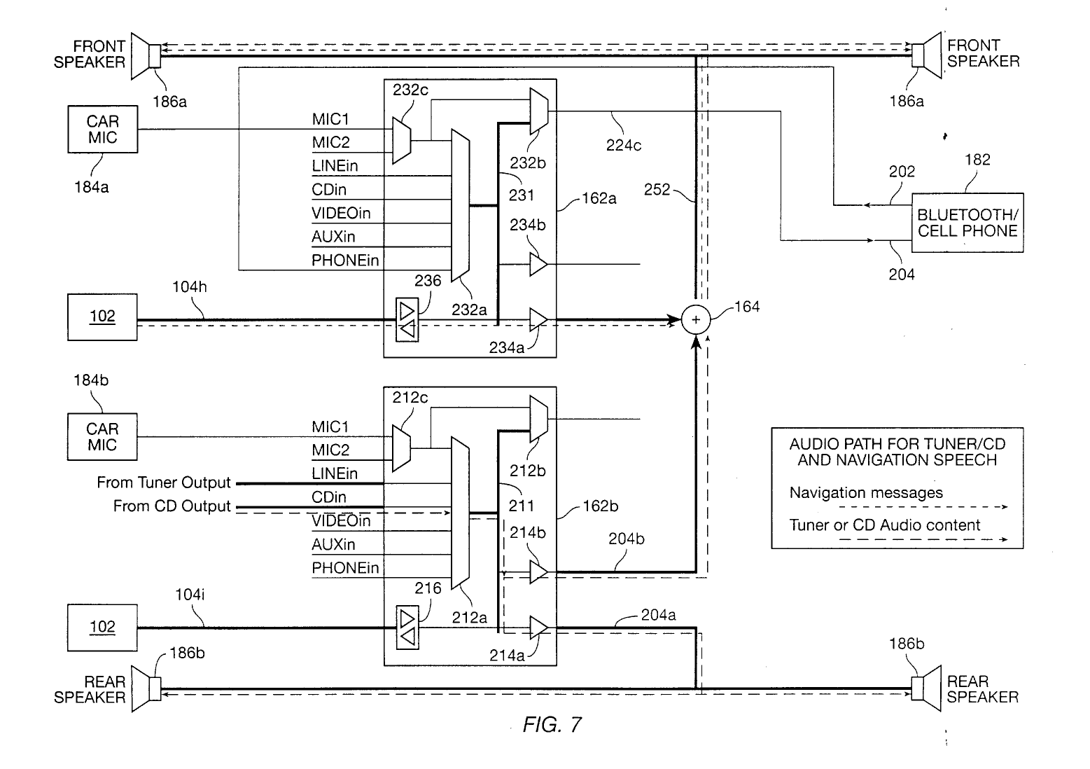

FIG. 7 shows a similar scenario as shown in FIG. 6. This figure illustrates that the first audio information can be provided by other audio sources, as for example, a CD player, a tuner, tape deck, an audio stream from the Internet, and so on. In the specific example shown in the figure, the audio stream is selected by the mux function 212a to deliver an audio stream from a CD player or tuner to the amplifiers 214a and 214b via the audio path 211. From that point on, processing of the audio stream is identical to the processing described for FIG. 6.

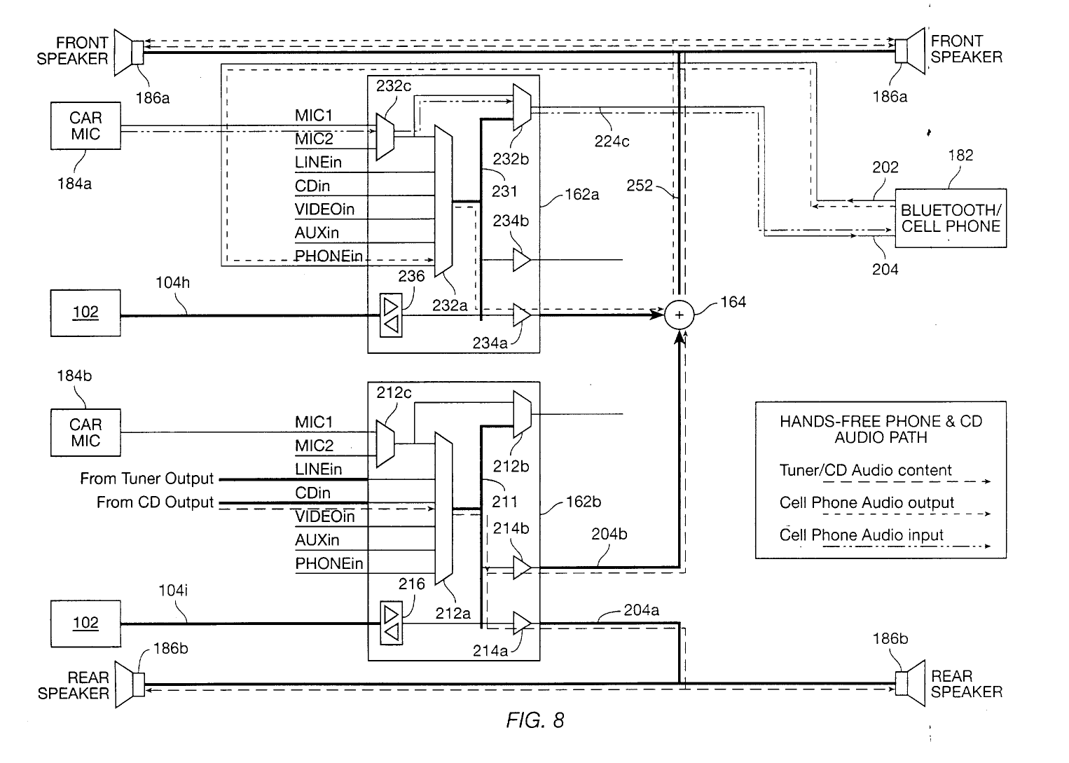

FIG. 8 shows another scenario, also similar to the one shown in FIG. 6. This figure illustrates that the second audio information can be provided by other sources, such as a communication device 182; e.g., a cell phone.

Referring again to FIG. 5 and also to FIG. 8, processing of the audio streams in this particular scenario is similar to the scenarios shown in FIGS. 6 and 7. Initially, suppose first audio information is being played (steps 502 and 504), e.g. from a CD player. As shown in the figure, the audio is processed by the codec 162b via amplifiers 214a and 214b and provided to the speaker(s) 186a and 186b.

When an incoming call from a cell phone occurs, the event can be detected (step 501). For example, the cell phone can send the Ring Indicator signal which will in turn interrupt the CPU. A suitable interrupt handling routine in the microcontroller software can generate appropriate control signals operate the codec to cause the amplifier functional unit 214b to alter the audio signal corresponding to the CD stream (step 506) such that when it is “played” by a speaker, its corresponding sound volume will be lower than the sound volume of the sound produced from the signal provided by the amplifier functional unit 214a. The signal produced by the amplifier 214b is a reduced-volume signal.

The codec 162a receives the caller's voice input via the PHONEin input and provides it to the output 224a. The mixer 164 combines (step 508) the signal representing the caller's audio and the reduced-volume signal from the codec 162b to produce a combined signal. The combined signal is provided to the speaker(s) 186a via the mixer output 252 (step 510). The resulting audio produced by the speaker(s) 186a comprises a sound component representative of the caller's voice and another sound component representative of audio from the CD. However, the later sound component is played at a lower volume which allows the user to hear the caller and yet continue to enjoy the CD. In the meantime, the volume of the sound from the speaker(s) 186b remains unchanged.

FIG. 8 shows an additional audio path wherein a microphone 184a allows the user to speak to the caller in a hands-free mode of operation. As can be seen, the codec 162a can be operated to receive audio from the microphone and provide that audio to the 224c output, via the multiplexing functional units 232c and 232b. The microphone audio is then provided to the outgoing channel 204 of the cell phone.

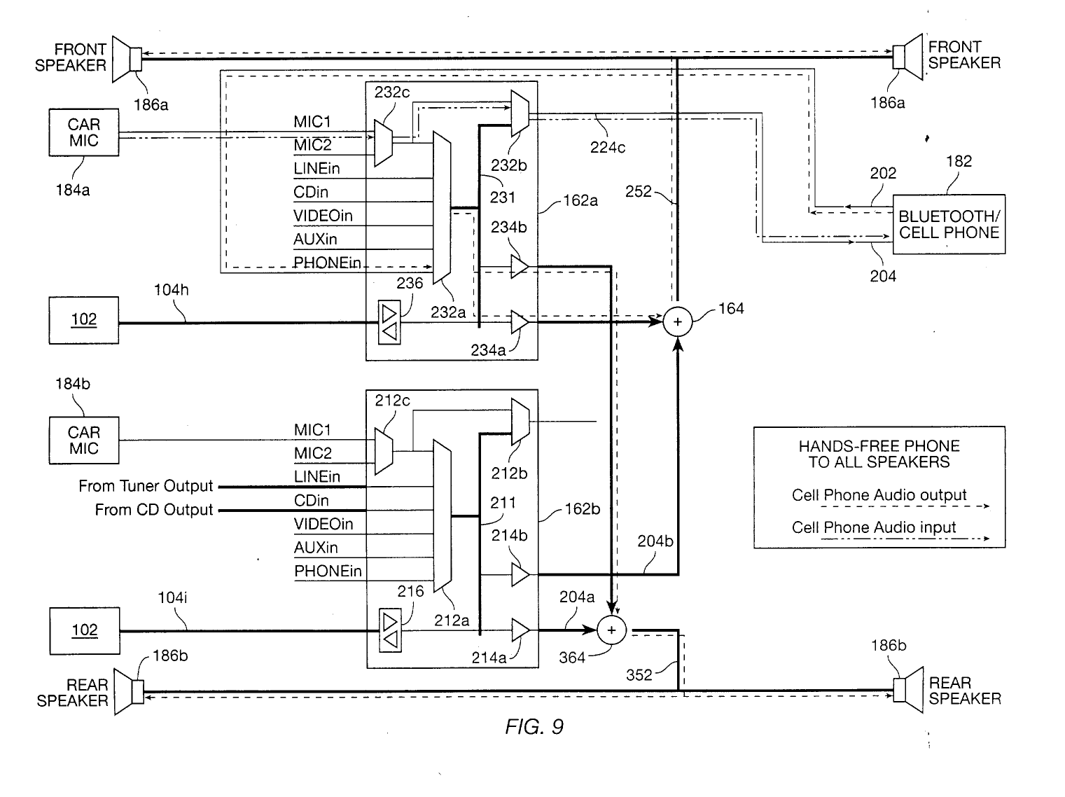

FIG. 9 shows a variation of the cell phone scenario illustrated in FIG. 8. Here, the codecs are configured as described in connection with FIG. 3. As will be explained, this configuration allows all the vehicle passengers to participate in the conversation.

Again, suppose that an audio source is being played over the speaker(s) 186a and 186b; for example, output from a tuner can be provided to the codec 162b via the LINEin input as first audio information. When an incoming call from the communication device 182 is detected, both amplifier functional units 214a and 214b are controlled to adjust an audio signal representative of the first audio information such that the volume of the audio when it is played over the speaker(s) 186a and 186b is reduced in both the speaker(s) 186a and the speaker(s) 186b. Thus, both outputs 204a and 204b produce reduced-volume signals.

The codec 162a receives second audio information from the cell phone 182 and provides a corresponding audio signal to the outputs 224a and 224b. The mixer 164 combines the reduced-volume signal from the output 204b of codec 162b and the signal from the output 224a of codec 162a to produce a combined signal on output 252. This combined signal is provided to the speaker(s) 186a. The mixer 364 combines the reduced-volume signal from output 204a of codec 162b with the signal from output 224b of codec 162a to produce a second combined signal which appears at the output 352 of the mixer. The second combined signal is provided to the speaker(s) 186b. Thus, in the scenario shown in FIG. 9, the first audio is reduced in volume for all the speakers so that all the passengers can hear the second audio from the cell phone caller while still being able to hear the first audio as background music.

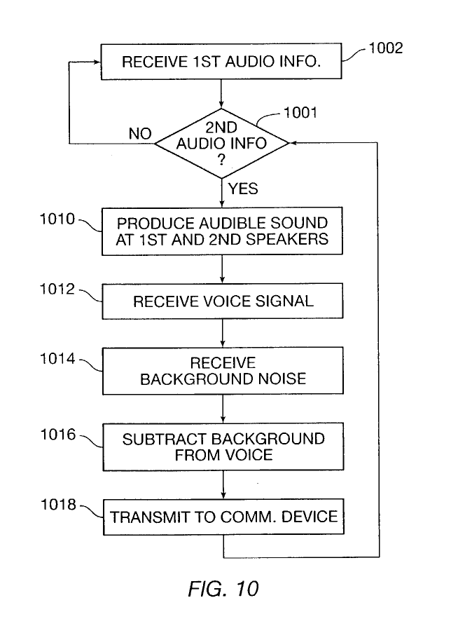

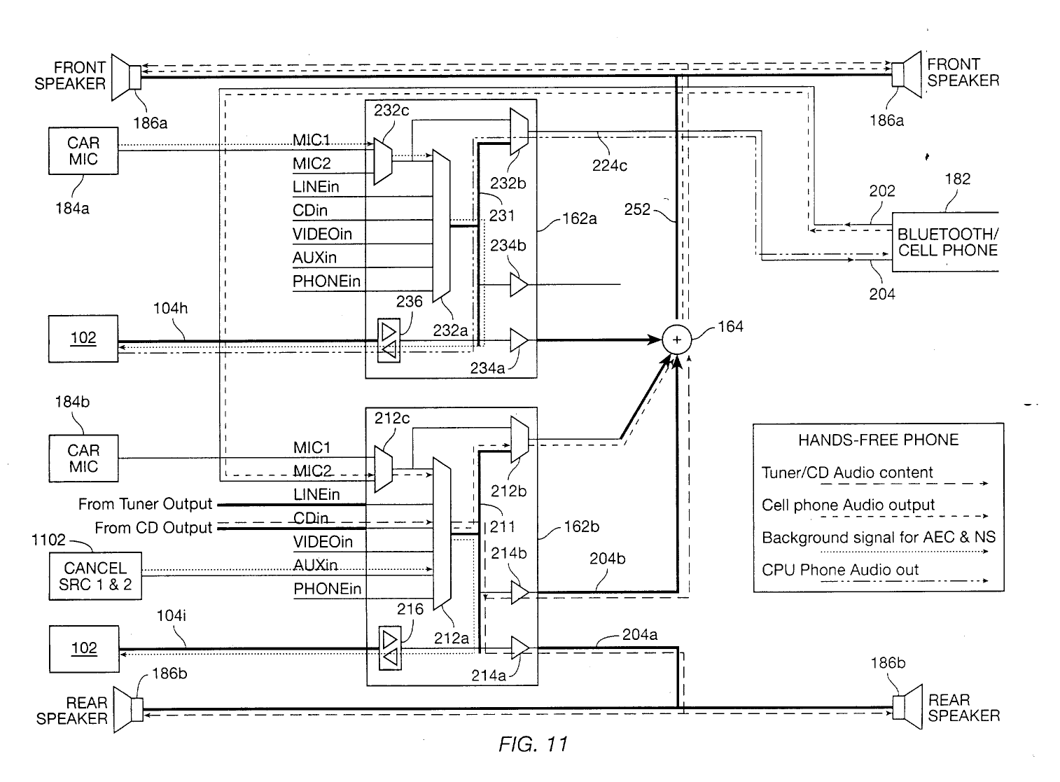

FIG. 10 is a high-level flow diagram highlighting the processing steps according to another embodiment of the present invention. FIG. 11 illustrates the audio stream flow according to the processing described in the flow chart.

In a step 1002, first audio information is received; e.g., FIG. 11 shows a CD audio stream being provided to the codec 162b. Audible sound representative of the first audio information is produced, in a step 1004, at the speaker(s) 186a via the audio path comprising the output 204b of the codec 162b and the output 252 of the mixer 164. Similarly, audible sound is produced at the speaker(s) 186b via the audio path comprising the output 204a of the codec 162b.

A communication device 182 (e.g., cell phone) is coupled to the microphone MIC1 input of codec 162b. When a second audio stream from the cell phone is detected (i.e., an incoming call), in a step 1001, appropriate control signals are issued to the functional unit represented by the amplifier 214b to adjust the audio signal of the CD stream (step 1006) such that when it is “played” by a speaker, its corresponding sound volume will be lower than the sound volume of the sound produced from the signal provided by the amplifier 214a. The signal produced by the amplifier 214b is a reduced-volume signal.

The cell phone audio stream provided over the MIC1 line is routed via muxes 212c and 212b to the output 204c. In this way, the codec 162b can provide an audio path for both the CD audio and the audio output of the cell phone. The signal provided at the output 204c is combined, in a step 1008, by the mixer 164 with the signal from the output 204b to produce a signal at the output 252. This signal is provided to the speaker(s) 186a, in a step 1010 to produce an audible sound comprising a sound component from the CD audio stream and a sound component from the cell phone output. Meanwhile, the CD audio stream that is delivered to the speaker(s) 186b remains unchanged.

As can be seen in the hands-free cell phone configuration of FIG. 11, a microphone 184a can be provided to pickup the speech audio of a passenger in the vehicle, in a step 1012. In accordance with this particular embodiment of the invention, additional microphones 1102 can be placed about the vehicle to pickup background noise (e.g., road noise), in a step 1014. The microphone audio and the background noise can be fed back to the microcontroller 102, where suitable noise cancellation software can subtract out (at least to some degree) the background noise from the audio pickup, in a step 1016. A noise-reduced audio is produced and provided back to the codec 162a, via the bus 104h. The mux 232b then directs the noise-reduced audio to the cell phone output 204, in a step 1018. This particular embodiment therefore further enhances cell phone usage by providing a noise-reduced speaking environment in addition to hands-free operation.

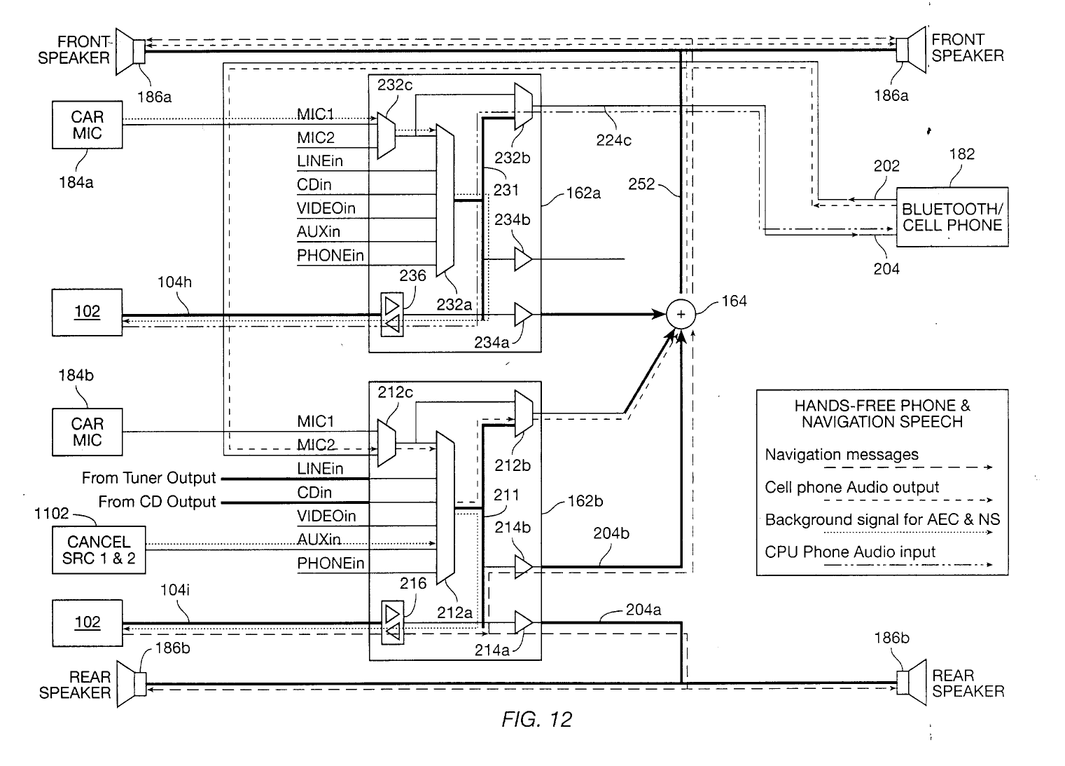

FIG. 12 illustrates a variation of the operating scenario presented in FIG. 11. Here, the CD input is substituted by the navigation system as the audio source, providing text-to-speech synthesized voice to the codec 162b over the bus 104i. The figure shows that when a second audio source such as the cell phone is present, the synthesized voice from the navigation system can be reduced in volume level for the speakers 186a, thereby allowing listeners proximate these speakers to hear the caller on the cell phone. The figure also illustrates the audio paths provided for performing noise cancellation on the speech audio of the person talking on the cell phone.

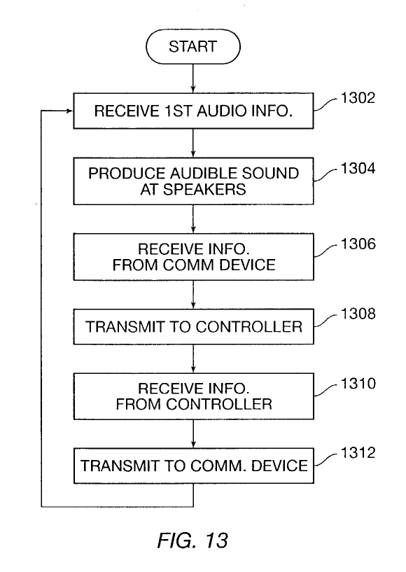

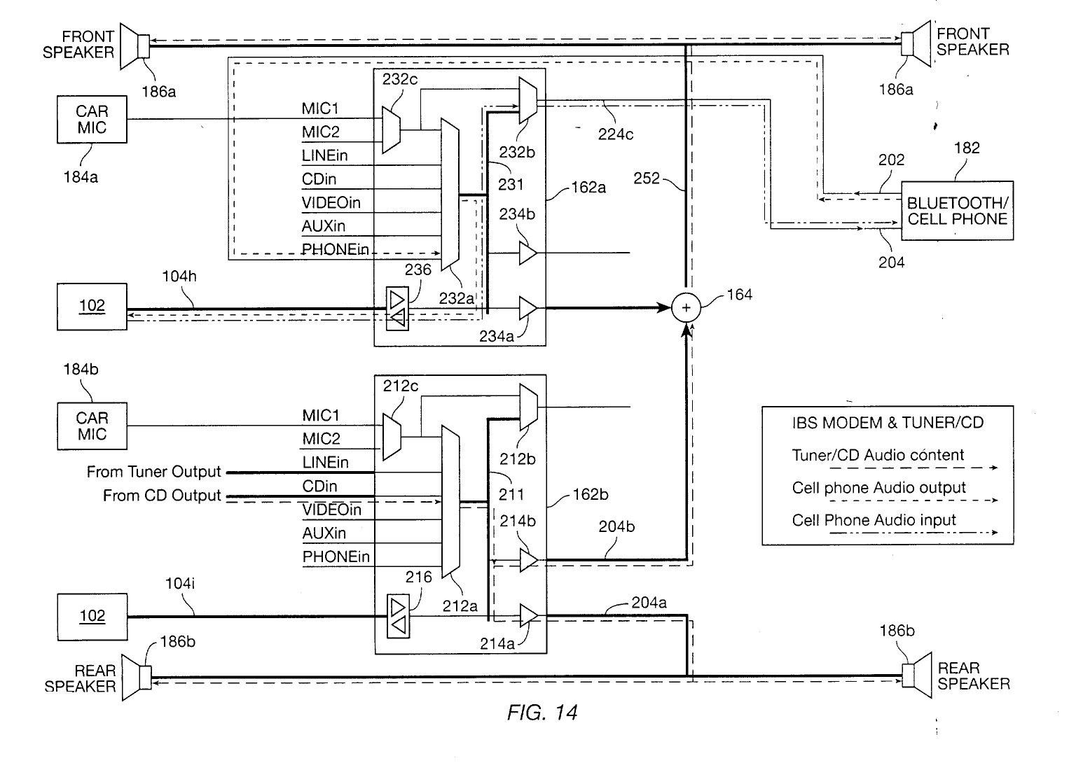

Refer now to FIG. 13 for a high level flow chart which highlights audio path processing according to another embodiment of the invention. FIG. 14 shows the configuration of audio paths in a specific implementation according to this embodiment of the invention.

In a step 1302, first audio information is received. For example, in FIG. 14, an MP3 audio stream is shown being received by codec 162b. The audio stream is provided to speakers 186a and 186b via the amplification functional units 214a and 214b and their associated audio paths, to produce audible sound in a step 1304. Thus, speaker(s) 186b are driven by an audio signal provided on an audio path comprising the output 204a. Speaker(s) 186a are driven by an audio signal provided on an audio path comprising the output 204b and the output 252 of the mixer 164.

In a step 1306, data from the communication device 182 is received at the PHONEin input of codec 162a. In this case, the communication device is an in-band signaling modem, which can be found in some cell phones. The data received from the device is transmitted, in a step 1308, to the microcontroller 102 over the bus 104h. Appropriate data processing can be performed depending on the nature of the data. For example, if the data is from a real-time stock quoting service, the information can be processed accordingly to produce a visual display on the LCD, e.g., a ticker tape graphic. If the data contains audio content, then it can be routed to the mixer 164 via the output 224a and combined with a reduced-volume signal of the first audio information produced at the output 204b in the manner previously described.

In a step 1310, the microcontroller 102 can provide outgoing data if needed. The audio path for the outgoing data is shown in FIG. 14 where the mux 232b directs the information received on bus 104h to the output 224c. The data is then delivered, in a step 1312, to the communication device 182 via its input 204.

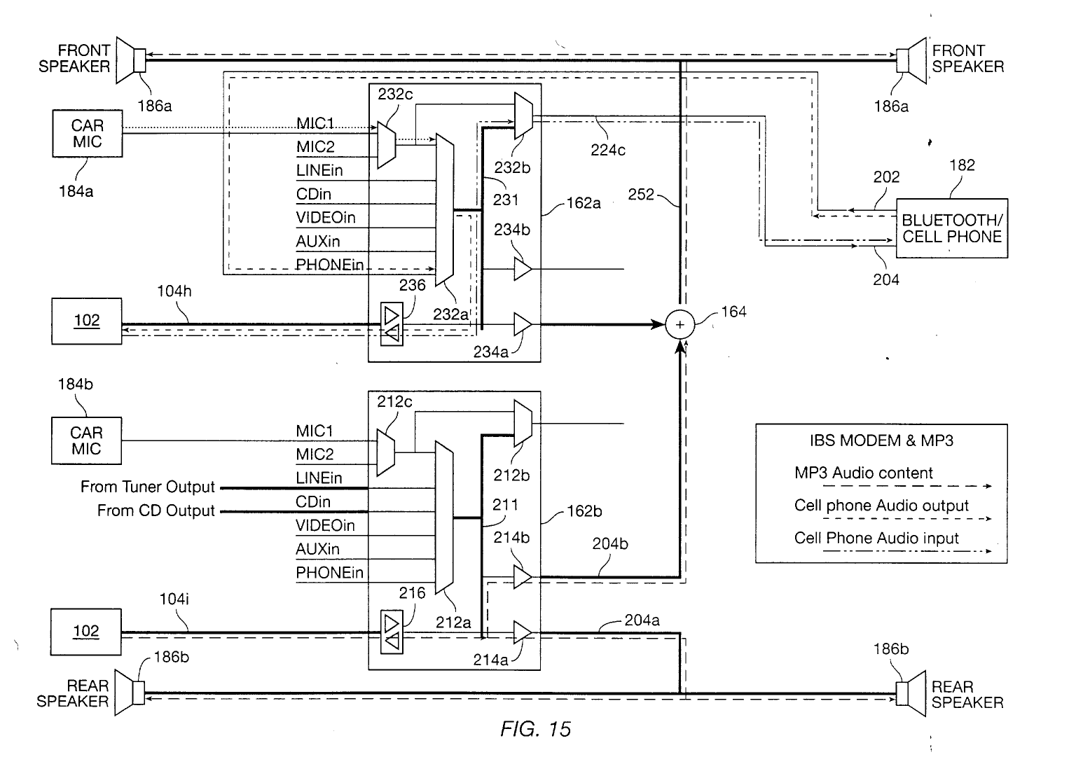

FIG. 15 shows an alternate operating scenario, illustrating that the source for the first audio information can be a CD player, a tuner, and so on.

What is claimed is:

1. A method for operating an in-vehicle audio system to provide audio to occupants in a vehicle comprising:
receiving first audio information;
producing a first audio signal from the first audio information;
providing the first audio signal to a first speaker system and to a second speaker system;
receiving second audio information;
producing a second audio signal from the second audio information; and
in response to receiving the second audio information, altering the first audio signal to produce an altered-volume signal, mixing the altered-volume signal and the second audio signal to produce a mixed audio signal, and providing the mixed audio signal to the first speaker system.

2. The method of claim 1 wherein a volume level of a first sound corresponding to the altered-volume signal is lower than a volume level of a second sound corresponding to the first audio signal, the first sound being produced by the first speaker system, the second sound being produced by the second speaker system.

3. The method of claim 1 wherein the first audio information is a digital signal and the step of producing the first audio signal includes converting the digital signal to produce an analog signal.

4. The method of claim 1 wherein the first audio information is received by a first coder-decoder (codec) device and the second audio signal is received by a second codec device.

5. The method of claim 1 wherein the altered-volume signal in the mixed audio signal is substantially muted.

6. The method of claim 1 further including altering the second audio signal to produce a second altered-volume signal, mixing the second altered-volume signal and the second audio signal to produce a second mixed audio signal, and providing the second mixed audio signal to the second speaker system.

7. The method of claim 1 further including receiving a volume control signal, wherein a volume level associated with the altered-volume signal is determined based on the volume control signal.

8. The method of claim 1 wherein the first audio information is provided by a compact disc player, a radio tuner, an audio tape player, or an MP3 source.

9. The method of claim 1 wherein the second audio information is provided by a navigation system or a telephonic device.

10. The method of claim 1 wherein the second audio information is an audio output of a telephonic device, the method further including receiving an ambient noise signal, receiving a speaker voice signal, performing noise cancellation on the speaker voice signal based on the ambient noise signal to produce a noise-reduced speaker voice signal, and providing the noise-reduced speaker voice signal to a voice input of the telephonic device.

11. A method of producing audio in a vehicle comprising:
receiving first audio information;
producing a first audible sound at a first location in the vehicle, the first audible sound comprising a first sound component corresponding to the first audio information and having a first volume level;
producing a second audible sound at a second location in the vehicle, the second audible sound comprising a second sound component corresponding to the first audio information and having a second volume level;
receiving second audio information; and
in response to receiving the second audio information, producing a third audible sound at the first location in the vehicle, the third audible sound comprising a third sound component and a fourth sound component, the third sound component corresponding to the first audio information and having a third volume level, the fourth sound component corresponding to the second audio information and having a fourth volume level,
wherein the first volume level is greater than the third volume level.

12. The method of claim 11 wherein the step of producing a third audible sound includes processing the first audio information through a first coder/decoder (codec) device to produce a first audio signal, processing the second audio information through a second codec device to produce a second audio signal, and mixing the first and second audio signals to produce a mixed signal, wherein the third audible sound is generated from the mixed signal.

13. The method of claim 11 wherein the first volume level is substantially equal to the second volume level.

14. The method of claim 11 wherein the first volume level is different from the second volume level.

15. The method of claim 11 wherein the step of producing a first audible sound includes providing a first audio signal to a first speaker system and the step of producing a second audible sound includes providing a second audio signal to a second speaker system.

16. The method of claim 11 wherein the first location is a front portion of the vehicle and the second location is a rear portion of the vehicle.

17. The method of claim 11 further including, in response to receiving the second audio information, producing a fourth audible sound at the second location in the vehicle, the fourth audible sound comprising a fifth sound component and a sixth sound component, the fifth sound component representative of the first audio information and having a fifth volume level, the sixth sound component representative of the second audio information and having a sixth volume level.

18. The method of claim 11 wherein the first and second audio information are first and second digital signals, respectively.

19. An in-vehicle audio system comprising audio circuitry operative to provide audio signals to a first speaker system and to a second speaker system, the audio circuitry comprising:
a first circuit operable to receive first audio information and configured to provide the first audio information to the first speaker system along a first audio path, the first circuit configured to provide the first audio information to the second speaker system along a second audio path;
a second circuit operable to receive second audio information;
a mixer circuit operable to produce a mixed signal representative of a combination of the first audio information and the second audio information, the mixer configured to provide the mixed signal to the first speaker along a third audio path; and
a first volume control component operable to reduce a volume level of a first sound produced by the first speaker system when the first speaker system receives the mixed signal, wherein the sound corresponds to the first audio information,
the first volume control component being configured to vary the volume level in response to presence of the second audio information.

20. The audio circuitry of claim 19 further comprising a second volume control component operable to reduce a volume level of a second sound produced by the second speaker system when the second speaker system receives the mixed signal, wherein the sound corresponds to the first information,
the second volume control component being configured to vary the volume level in response to presence of the second audio information.

21. The audio circuitry of claim 19 wherein the first audio information originates from a compact disc player, a radio tuner, an audio tape player, or an MP3 source.

22. The audio circuitry of claim 19 wherein the second audio information originates from navigation system or a telephonic device.

23. The audio circuitry of claim 19 wherein the first and second circuitry each is a coder/decoder (codec) device.

24. An in-vehicle audio system comprising an audio control component, a first speaker system and a second speaker system, the audio control component comprising:
first means for processing first audio information, the first means having first and second outputs;
second means for processing second audio information, the second means having first and second outputs;
first path means for providing an audio signal from the first output of the first means and an audio signal from the second output of the second means to the first speaker system to produce a first sound; and
second path means for providing at least an audio signal from the second output of the first means to the second speaker system to produce a second sound,
wherein the first means is operable to alter the audio signal from its first output such that the first audio information produced in the first sound has a lower volume than the first audio information produced in the second sound when the second audio information is present.

25. The in-vehicle audio system of claim 24 wherein the first means is a first coder/decoder and the second means is a second coder/decoder.

26. The in-vehicle audio system of claim 24 wherein the first path means includes a mixer circuit having:
a first input coupled to receive the audio signal from the first output of the first means;
a second input coupled to receive the audio signal from the first output of the second means; and
an output coupled provide a mixed signal to the first speaker system,
the mixer circuit operative to produce the mixed signal from the audio signals.
